(19) United States
(12) Patent Application Publication
(10) Pub. No.: US 2014/0117192 A1
(43) Pub. Date: May 1, 2014

(54) ELECTRONIC DEVICE COVER

(71) Applicant: HON HAI PRECISION INDUSTRY CO., LTD., New Taipei (TW)

(72) Inventors: HUNG-JIA HUANG, New Taipei (TW); CHUNG-HSING YANG, New Taipei (TW)

(21) Appl. No.: 13/930,195

(22) Filed: Jun. 28, 2013

(30) Foreign Application Priority Data
Oct. 31, 2012 (TW) 101140331

(51) Int. Cl. H05K 5/03; F16M 13/02; F16M 11/00

(52) U.S. Cl. CPC H05K 5/03; F16M 11/00; F16M 13/022
USPC 248/346.04

(57) ABSTRACT

A cover includes a placing plate, a supporting plate, and a connecting portion. The placing plate is placed on a desktop. The supporting plate supports an electronic device. The connecting portion is connected between the placing plate and the supporting plate. A plurality of positioning pieces is placed on the connecting portion, a first joint between the connecting portion and the placing plate, and a second joint between the connecting portion and the supporting plate. The plurality of positioning pieces is elastically bent in different angles to position the supporting plate in different inclined positions.

### BACKGROUND

1. Technical Field

The present disclosure relates to a cover for an electronic device.

2. Description of Related Art

An electronic device, such as a tablet computer, is usually placed in a cover to prevent the electronic device from being damaged. The electronic device may also need a support to stand on a desktop. However, it may be cumbersome to equip both a cover and a supporter for the electronic device.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of a cover for an electronic device.

FIG. 2 is a side view of the cover and the electronic device of FIG. 1 in an open position.

FIG. 3 is a front view of the cover of FIG. 1.

FIG. 4 is a side view of the cover and the electronic device of FIG. 1 in a closed position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

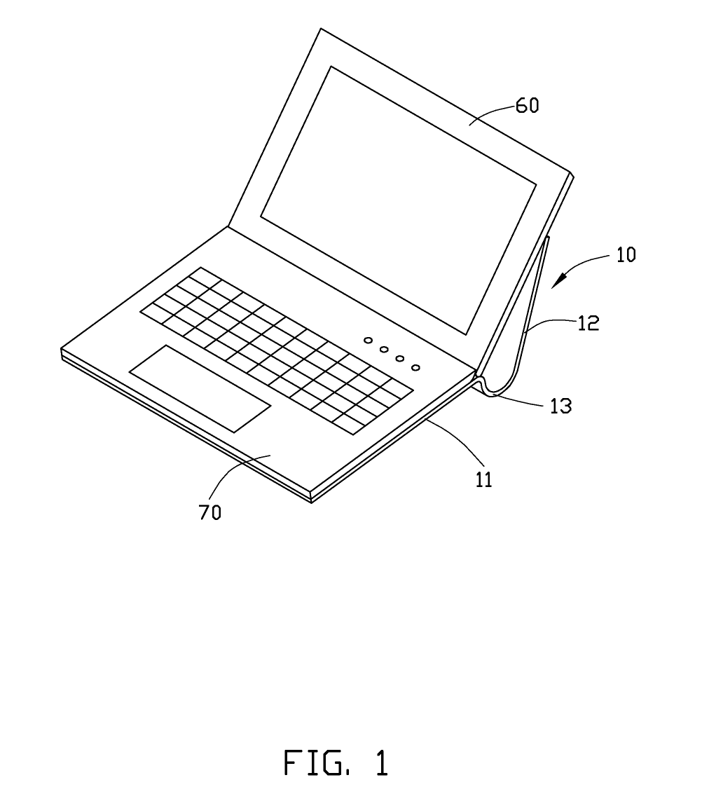

FIG. 1 shows an embodiment of a cover 10 for an electronic device 60. The cover 10 includes a placing plate 11, a supporting plate 12, and a connecting portion 13. In one embodiment, the electronic device 60 is a tablet computer.

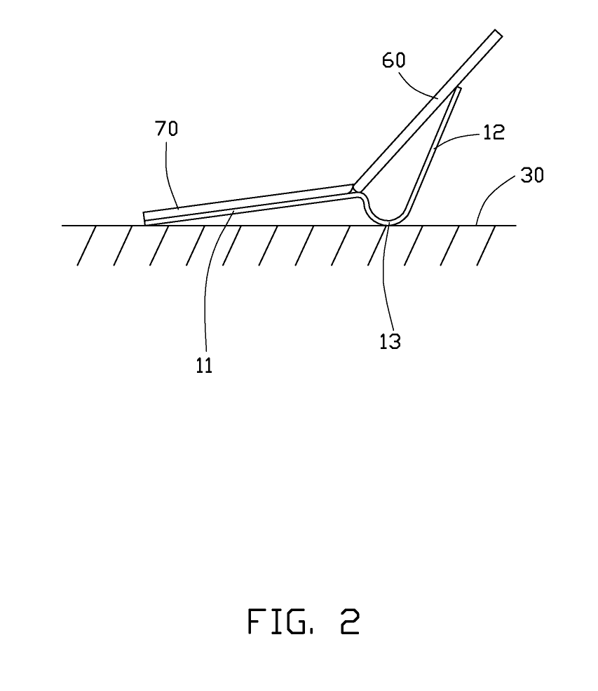

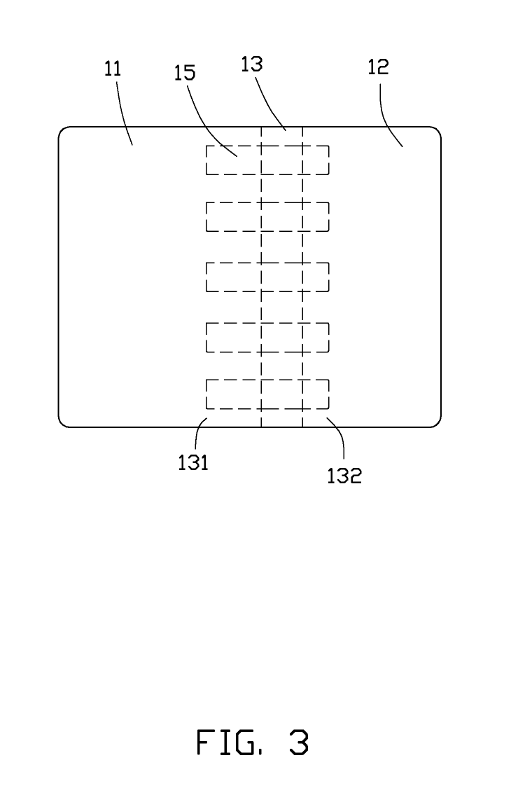

Referring to FIGS. 1 to 3, the connecting portion 13 is a semicircular elastic piece. One end of the connecting portion 13 is connected to the placing plate 11, while the other end of the connecting portion 13 is connected to the supporting plate 12. A plurality of positioning pieces 15 is placed on the connecting portion 13, a first joint 131 between the connecting portion 13 and the placing plate 11, and a second joint 132 between the connecting portion 13 and the supporting plate 12. The positioning pieces 15 can be bent in different shapes and positioned in different bent positions.

In use, the placing plate 11 and the connecting portion 13 are placed on a desktop 30. The connecting portion 13 is bent and positioned in an open position. In the open position, the supporting plate 12 is inclined with respect to the desktop 30. The inclined supporting plate 12 supports the electronic device 60 in an inclined position. Therefore, the electronic device 60 is conveniently supported on a desktop.

The electronic device 60 can be positioned differently by bending the connecting portion 13 and the plurality of positioning pieces 15 in different angles. A keyboard 70 is placed on the placing plate 11 to electronically connect to and control the electronic device 60.

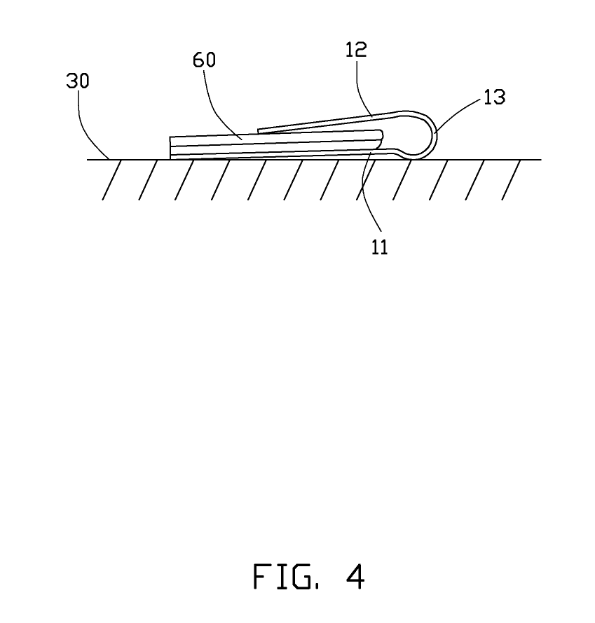

Referring to FIG. 4, the connecting portion 13 and the plurality of positioning pieces 15 are bent to sandwich the electronic device 60 between the placing plate 11 and the supporting plate 12. Therefore, the placing plate 11 and the supporting plate 12 together protect the electronic device 60 from being damaged.

In the above embodiment, the cover 10 not only protects the electronic device 60 from being damaged, but also supports the electronic device 60 in different inclined positions on a desktop.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A cover, comprising:
a placing plate configured to be placed on a desktop;
a supporting plate configured to support an electronic device thereon;
a connecting portion connected between the placing plate and the supporting plate, a plurality of positioning pieces on the connecting portion, a first joint between the connecting portion and the placing plate, and a second joint between the connecting portion and the supporting plate, the plurality of positioning pieces is adapted to be elastically bent in various angles accordingly to incline positions of the supporting plate.

2. The cover of claim 1, wherein the connecting portion is an elastic piece shaped to a semicircle.

3. The cover of claim 1, wherein a keyboard is placed on the placing plate, the keyboard is adapted to be electrically connected to the electronic device.

4. The cover of claim 1, wherein the plurality of positioning pieces is configured to be elastically bent to sandwich the electronic device between the supporting plate and the placing plate.

5. The cover of claim 1, wherein the connecting portion is configured to be placed on the desktop.

6. The cover of claim 1, wherein the electronic device is a tablet computer.

7. A cover, comprising:
a placing plate;
a supporting plate configured to support an electronic device thereon;
a connecting portion connected between the placing plate and the supporting plate, a plurality of positioning pieces on the connecting portion, a first joint between the connecting portion and the placing plate, and a second joint between the connecting portion and the supporting plate, the plurality of positioning pieces is adapted to be elastically bent to sandwich the electronic device between the supporting plate and the placing plate.

8. The cover of claim 7, wherein the connecting portion is an elastic piece shaped to a semicircle.

9. The cover of claim 7, wherein a keyboard is placed on the placing plate, the keyboard is adapted to be electrically connected to the electronic device.

10. The cover of claim 7, wherein the plurality of positioning pieces is configured to be elastically bent in various angles according to incline positions of the supporting plate.

11. The cover of claim 7, wherein the connecting portion and the placing plate are configured to be placed on a desktop.

12. The cover of claim 7, wherein the electronic device is a tablet computer.
